(19) United States
(12) Patent Application Publication
(10) Pub. No.: US 2026/0098891 A1
(43) Pub. Date: Apr. 9, 2026

(54) SYSTEMS AND METHODS FOR DETECTING ATTRIBUTES OF A LOCAL ELECTRICAL GRID OF AN ILLUMINATION SYSTEM

(71) Applicant: Tondo Smart LTD., Or Yehuda (IL)

(72) Inventors: Philip DESAUTELS, Springvale, ME (US); Micha BEN-EZRA, Or Yehuda (IL); Guy SAADI, Or Yehuda (IL)

(21) Appl. No.: 19/353,629

(22) Filed: Oct. 9, 2025

Related U.S. Application Data
(60) Provisional application No. 63/705,051, filed on Oct. 9, 2024.

(51) Int. Cl. G01R 31/08

(52) U.S. Cl. CPC G01R 31/088; G01R 31/086

(57) ABSTRACT

Systems and methods for determining one or more attributes of a local (electrical) grid of an illumination systems. In some embodiments the attributes are determined at least by receiving data pertaining at least to one or more electrical attributes of the local grid and/or of the illumination system, at least from one or more sensors; and processing the received data to determine, based on the processing of the received data, one or more attributes of the illumination system and/or its local grid. Disclosed embodiments also enable generating a grid map displaying a layout of the local grid of the illumination system such as relative position of light fixtures of the illumination system over its local grid.

### TECHNICAL FIELD

The present invention relates in general to the field of detection of electrical attributes of a system and more particularly to detection of electrical attributes pertaining to an illumination system that uses multiple light fixtures for illumination of an area of interest, where the light fixtures are electrically connected to a main power source via a local (electrical) grid.

### BACKGROUND

When light of a light fixture is switched on, especially when using a light fixture with one or more light emitting diodes (LEDs) as its one or more light sources, an inrush current is often created, which is a short-term surge in power demand by the light fixture or one or more light sources thereof. The power demand for the inrush current caused by the on-switching of the light fixture or one or more light sources thereof, is substantially greater than the steady state power demand for the ongoing operation of the light fixture.

Inrush current causes various problems especially when supplying power to an illumination system that includes multiple light fixtures all connected to a main power source (such as a main electrical grid) through a local (electrical) grid and especially when several, many or all of these light fixtures of the same illumination system are to be switched on at the same time causing a large and abrupt demand for power supply, which may not be enabled by the power source used by the illumination system, for such a short period of time.

Moreover, electrical connectivity between the different light fixtures of an illumination system through its local electrical grid, connecting the light fixtures of the illumination system, may be set in a web-like, string or cascaded manner in which the electrical power line is longer for some of the fixtures in respect to one or more other fixtures and/or to the power source, making it harder to supply high inrush current required power to switch ‘on’ light fixtures having more other light fixtures ahead of them downstream the local grid or part thereof.

Power supply to the light fixtures of an illumination system is often divided to one or more primary circuits, each subdivided into several branch circuits, each branch circuit may include one or more “strings”, where each string may be designed to supply power to one or several light fixtures of the illumination system. Each light fixture of the illumination system may be on a same or different string and/or the same or different phase of one or more other light fixtures of the illumination system, where the power supply source may be a single-phase or multi-phase alternating current (AC) power supply source.

FIGS. 1A and 1B show a schematic illustration of how a 3-phase local grid 10 (FIG. 1A) connectable to an AC power supply source 11 or a single-phase local grid 20 (FIG. 1B) connectable to AC power supply source 21 can be branched through at least one primary circuit 12 or 22, respectively, to several branch circuits such as branch circuits 13a and 13b, or 23a and 23b, respectively. Each branch circuit such as of 13a, 13b, 23a and/or 23b, can include one or more strings for supplying power to one or more light fixtures thereof, such as strings 14 or 24, respectively.

In a given string of light fixtures, power is supplied upstream of all light fixtures, and all fixtures are downstream of the supplied power. When multiple strings of light fixtures are on the same circuit, they share the same power supply of their corresponding branch circuit.

Each branch circuit and/or string may have an inherent voltage drop along its wiring/grid length due to the resistance and inductance of the wires of the circuit/string and also due to connection devices, elements and/or points of that part of the local grid of the illumination system. Typically, the longer the wiring distance downstream and/or the more divided/branched that string or local grid part in respect to the specific light fixture, the greater the inherent voltage drop it will cause.

FIG. 2 shows a schematic illustration of a string of light fixtures forming a “string circuit” 30 receiving a single-phase power supply 31 from its corresponding branch circuit. The wiring 31 of the string circuit has its inherent resistance R and its inherent inductance H influencing voltage drops and/or inrush current demand. Each light fixture from all the light fixtures of the string such as a set of light fixtures from 33a to 33n, where “n” is an integer number, has its own electrical resistance R1/Rn and inductance H1/Hn and its own inrush current demand, depending on its downstream location in relation to its respective power supply 31 and optionally also depending on other fixture(s)'s attributes influencing power supply demand and/or attributes at each given moment such as on/off-switching timing.

The location of each light fixture 33a to 33n in respect to each of the other light fixtures and/or in respect to the power supply 31 and optionally also wire lengths from each light fixture to another and/or to the power supply 31 may also influence power supply demand for inrush current, voltage drops and/or ongoing operation of each light fixture 33a-33n of the string circuit 30.

Other characteristics or external parameters may influence power supply demand for each light fixture such as temperature, number of phases of the power supply 31, number of circuits and wiring (grid) layout thereof, type of each light fixture and/or each light source of each light fixture, fixture state or operation mode such as on, off or dimming level, etc.

In many cases, the actual grid layout and relative location of each light fixture in respect to the overall local grid and/or to the updated operation state/mode of each light fixture of the illumination system is partially or utterly unknown, making it extremely challenging to control or operate illumination without experiencing power supply impairments such as power/voltage drops, inrush current based failures, and/or other power supply and/or illumination issues, severely affecting illumination and/or power consumption and/or power supply efficiency.

### SUMMARY

Aspects of disclosed embodiments pertain to an analysis system for determination of one or more attributes of a local grid of an illumination system, wherein the illumination system comprises multiple light fixtures electrically connected through the local grid, the analysis system comprising at least:
at least one processing module configured to:
receive data pertaining at least to one or more electrical attributes of the local grid and/or of the light fixtures of the illumination system, from one or more sensors; and
process the received data to determine, based on the processing of the received data, one or more attributes of the local grid and/or of the illumination system.

According to some embodiments of the analysis system, the one or more attributes pertain to one or more of:
state of one or more of the light fixtures or one or more components of one or more of the light fixtures of the illumination system;
failures in the local grid and/or in one or more of the light fixtures of the illumination system;
inrush current of one or more of the light fixtures of the illumination system;
one or more phases of the electrical power of one or more of the light fixtures of the illumination system;
one or more voltage drops of one or more of the light fixtures of the illumination system;
sub-unity power factor in power of one or more of the light fixtures of the illumination system;
overload in one or more electrical circuits of the local grid of the illumination system;
relative position of the light fixtures of the illumination system over the local grid, in relation to the local grid and/or to one or more other light fixtures of the illumination system;
geolocation of each light fixture of the illumination system;
layout of the local grid and/or of the light fixtures of the illumination system.

According to some embodiments of the analysis system, each sensor may be configured to one or more of:
sense one or more electrical attributes of at least one of the light fixtures;
sense illumination attributes of at least one of the light fixtures;
sense one or more phases of electrical signals delivered and/or outputted to/from at least one of the light fixtures; and/or
sense timing of one or more phases of the electrical signals delivered and/or outputted to from at least one of the light fixtures.
sense one or more electrical attributes of the local grid;
sense a change in the local grid from previously established ‘normal’ benchmarks;
sense electrical attributes of a power supply source connectable to the local grid of the illumination system for suppling power thereto.

According to some embodiments of the analysis system, the sensing of the one or more electrical, timing, phases, electrical and/or illumination attributes of at least one of the light fixtures of the illumination system may be done by using one or more sensors, each sensor being associated with one or more of the light fixtures of the illumination system.

According to some embodiments of the analysis system, the analysis system may be further configured to control at least some of the light fixtures of the illumination system based on the determined one or more attributes of the local grid of the illumination system and/or updated attributes of the specific light fixture, wherein the controlling of at least some of the light fixtures may be done via controllers, wherein each controller may be located in proximity to, attached to or embedded in a light fixture from the light fixtures of the illumination system.

According to some embodiments of the analysis system, each sensor may include a timing device that is synchronized with other timing devices of the other fixture devices of the illumination system, for determining timing of each phase of an alternating current (AC) supplied to the light fixture associated with the specific timing device, for determining which light fixtures of the illumination system share the same phase.

According to some embodiments of the analysis system, the analysis system may be further configured to determine updated required control operations for controlling and/or adjusting one or more operation properties of one or more of the light fixtures of the illumination system for increasing illumination and/or power consumption efficiency.

According to some embodiments of the analysis system, the analysis system may be configured to send determined updated required control operations information to each controller of each light fixture of the illumination system determined to require one or more control operations, wherein each controller is configured to receive updated required operation control actions data or signals and control the light fixture it is associated therewith accordingly.

According to some embodiments of the analysis system, the one or more updated required control operations are determined also based on obtained updated illumination requirements and/or limitations of the illumination system.

According to some embodiments of the analysis system, the increasing illumination and/or power consumption efficiency is done by one or more of:
automatically and dynamically setting a timing of a power up of one or more of the light fixtures of the illumination system, to minimize the impact of inrush current and/or voltage drop and/or sub-unity power factor along at least one string or a circuit of the local grid;
automatically and dynamically adapting dimming properties of each light fixture of the illumination system to minimize the impact of current and/or voltage variations and/or sub-unity power factor along at least one string or circuit of the local grid.

According to some embodiments of the analysis system, the analysis system may be further configured to generate and display a grid map of the local grid of the illumination system, where the grid map or parts thereof may be configured for being displayable via one or more user devices.

According to some embodiments of the analysis system, the generated grid map enables displaying of the determined one or more attributes of the local grid of the illumination system and/or one or more attributes of the illumination system including at least relative positions of each the light fixtures of the illumination over the local grid.

According to some embodiments of the analysis system, the system may be further configured to:
detect changes in the one or more attributes of the local grid; and
display in real time or near real time the detected changes in the one or more attributes of the local grid over the generated grid map.

According to some embodiments of the analysis system, the analysis system may be configured to use one or more additional sensors for sensing one or more attributes of one or more of: the local grid, the main power supply source feeding the local grid, and/or one or more of the light fixtures of the illumination system.

According to some embodiments of the analysis system, the one or more sensors comprise one or more of: a timing device, a clock, a voltage sensor, a current sensor, an optical sensor for sensing one or more optical attributes of one or more of the light fixtures, a positioning sensor.

According to some embodiments of the analysis system, the analysis system further comprises a communication unit for enabling communication between the at least one processing module and one or more of:
each of the one or more sensors, configured to detect one or more attributes pertaining to the local grid and/or to the illumination system;
at least one external information source; and/or
at least one control center, configured to control a main power supply source supplying power to the illumination system via the local grid.

According to some embodiments of the analysis system, the analysis system further comprises a planning platform, configured to enable generation of illumination system plans local grids thereof for a specific area of interest (AOI) based on one or more of:
obtained illumination requirements and/or limitations;
obtained power consumption requirements and/or limitations;
user input information;
AOI information.

According to some embodiments of the analysis system, the planning platform may be further configured for one or more of:
automatic generation of an optimized illumination plan based at least of information pertaining to the AOI in which the illumination system is to be located;
enabling users to manually generate and/or adjust illumination system plans via one or more planning tools of the planning platform;
displaying of generated illumination system plans.

Other aspects of disclosed embodiments pertain to a method for determination of one or more attributes of an electrical local grid of an illumination system, wherein the illumination system comprises multiple light fixtures electrically connected through the local grid, the method including a processing circuitry configured for:
receiving data pertaining at least to one or more electrical attributes of the local grid and/or of the illumination system, at least from one or more sensors; and
processing the received data to determine, based on the processing of the received data, one or more attributes of the illumination system and/or its local grid.

According to some embodiments of the method, the one or more attributes pertain to one or more of:
state of one or more of the light fixtures or one or more components of one or more of the light fixtures of the illumination system;
failures in the local grid and/or in one or more of the light fixtures of the illumination system;
inrush current of one or more of the light fixtures of the illumination system;
one or more phases of the electrical power of one or more of the light fixtures of the illumination system;
one or more voltage drops of one or more of the light fixtures of the illumination system;
sub-unity power factor in power of one or more of the light fixtures of the illumination system;
overload in one or more electrical circuits of the local grid of the illumination system;
relative position of the light fixtures of the illumination system over the local grid, in relation to the local grid and/or to one or more other light fixtures of the illumination system;
geolocation of each light fixture of the illumination system;
layout of the local grid and/or of the light fixtures of the illumination system.

According to some embodiments of the method, the method further comprises one or more of:
obtaining one or more electrical attributes of at least one of the light fixtures;
obtaining illumination attributes of at least one of the light fixtures;
obtaining one or more phases of electrical signals delivered and/or outputted to/from at least one of the light fixtures; and/or
obtaining timing of one or more phases of the electrical signals delivered and/or outputted to/from at least one of the light fixtures;
obtaining one or more electrical attributes of the local grid;
obtaining a change in the local grid from previously established ‘normal’ benchmarks;
obtaining electrical attributes of a power supply source connectable to the local grid of the illumination system for suppling power thereto.

According to some embodiments of the method, the obtaining of the one or more electrical, timing, phases, electrical and/or illumination attributes of at least one of the light fixtures of the illumination system is done by using one or more sensors, each sensor being associated with one or more of the light fixtures of the illumination system.

According to some embodiments, the method further comprise the step of controlling at least some of the light fixtures of the illumination system based on the determined one or more attributes of the local grid of the illumination system and/or updated attributes of the specific light fixture, wherein the controlling of at least some of the light fixtures is done via controllers, wherein each controller is located in proximity to, attached to or embedded in a light fixture from the light fixtures of the illumination system.

According to some embodiments of the method, each sensor may comprise a timing device that is synchronized with other timing devices of the other fixture devices of the illumination system, for determining timing of each phase of an alternating current (AC) supplied to the light fixture associated with the specific timing device, for determining which light fixtures of the illumination system share the same phase.

According to some embodiments, the method further comprises the step of: determining updated required control operations for controlling and/or adjusting one or more operation properties of one or more of the light fixtures of the illumination system for increasing illumination and/or power consumption efficiency.

According to some embodiments, the method further comprises the step of: sending determined updated required control operations information to each controller of each light fixture of the illumination system determined to require one or more control operations, where each controller y configured to receive updated required operation control actions data or signals and control the light fixture it is associated therewith accordingly.

According to some embodiments of the method, the one or more updated required control operations may be determined also based on obtained updated illumination requirements and/or limitations of the illumination system.

According to some embodiments of the method, the increasing illumination and/or power consumption efficiency is done by one or more of:
automatically and dynamically setting a timing of a power up of one or more of the light fixtures of the illumination system, to minimize the impact of inrush current and/or voltage drop and/or sub-unity power factor along at least one string or a circuit of the local grid;
automatically and dynamically adapting dimming properties of each light fixture of the illumination system to minimize the impact of current and/or voltage variations and/or sub-unity power factor along at least one string or circuit of the local grid.

According to some embodiments, the method further comprises the steps of: generating and displaying a grid map of the local grid of the illumination system, where the grid map or parts thereof is configured for being displayable via one or more user devices.

According to some embodiments of the method, the generated grid map may enable displaying of the determined one or more attributes of the local grid of the illumination system and/or one or more attributes of the illumination system including at least relative positions of each the light fixtures of the illumination over the local grid.

According to some embodiments, the method may further comprise the steps of:
detecting changes in the one or more attributes of the local grid; and
displaying in real time or near real time the detected changes in the one or more attributes of the local grid over the generated grid map.

According to some embodiments of the method, the one or more sensors may comprise one or more of: a timing device, a clock, a voltage sensor, a current sensor, an optical sensor for sensing one or more optical attributes of one or more of the light fixtures, a positioning sensor.

According to some embodiments, the method may comprise the step of: enabling communication with one or more of: each of the one or more sensors, configured to detect one or more attributes pertaining to the local grid and/or to the illumination system; at least one external information source; and/or at least one control center, configured to control a main power supply source supplying power to the illumination system via the local grid.

According to some embodiments, the method may comprise the step of: providing a planning platform, configured to enable generation of illumination system plans local grids thereof for a specific area of interest (AOI) based on one or more of:
obtained illumination requirements and/or limitations;
obtained power consumption requirements and/or limitations;
user input information;
AOI information.

According to some embodiments of the method, the planning platform may be further configured for one or more of:
automatic generation of an optimized illumination plan based at least of information pertaining to the AOI in which the illumination system is to be located;
enabling users to manually generate and/or adjust illumination system plans via one or more planning tools of the planning platform;
displaying of generated illumination system plans.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings, in which:

FIGS. 1A and 1B show a schematic illustration of a 3-phase local grid (FIG. 1A) and a single-phase local grid (FIG. 1B);

FIG. 2 is a schematic illustration of a single-phase string circuit of an illumination system;

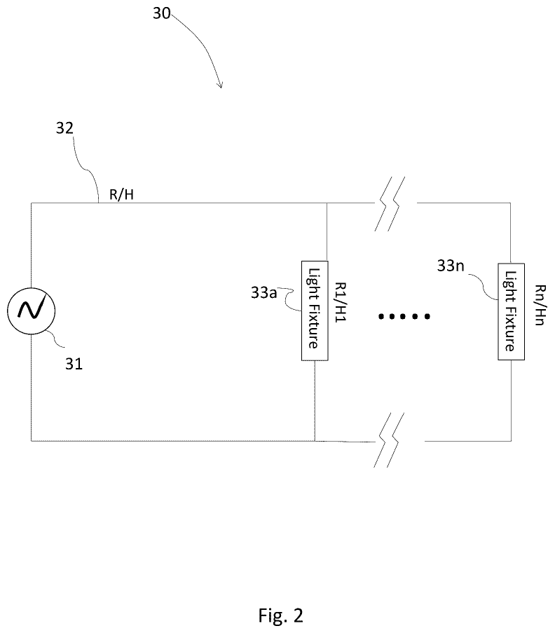

FIG. 3 is a block diagram, schematically illustrating an analysis system for determination of one or more attributes of an electrical local grid of an illumination system, according to some embodiments;

FIG. 4 shows main components of the analysis system, according to some embodiments;

FIG. 5 shows main components of a controller of a light fixture, according to some embodiments, in which one or more sensors are embedded in controller of a specific light fixture of the illumination system; and

FIG. 6 is a flowchart, schematically illustrating main steps of a method for determination of one or more attributes of a local grid of an illumination system, according to some embodiments.

### DETAILED DESCRIPTION OF EMBODIMENTS

In the following detailed description, numerous specific details are set forth in order to provide a thorough understanding of the presently disclosed subject matter. However, it will be understood by those skilled in the art that the presently disclosed subject matter may be practiced without these specific details. In other instances, well-known methods, procedures, and components have not been described in detail so as not to obscure the presently disclosed subject matter.

Inrush current can be sensed in a circuit for example by using one or more designated sensors per each light fixture of an illumination system such as an AC (alternating current) or DC (direct current) current meters/sensors.

Illumination controllers, each associated with a different light fixture of the illumination system, can be used for dimming/switching control of the specific light fixture and also for omni or bi-directionally communicating with a central control and/or monitoring system/device/unit.

Some available lighting controllers can geolocate themselves e.g., by using a variety of means such as a positioning sensor using, for example, but not limited to satellite and/or radio triangulation.

Some controllers of disclosed embodiments, may have integrated capabilities to sense electrical attributes of the electricity being supplied to the respective light fixture, associated with the specific sensor(s) sensing attributes such as, for example, voltage, current, flux, frequency, power factor, phase, power/energy consumption, etc. These sensors may enable direct measuring of electrical attribute(s) of the light fixture and/or one or more properties that enable determining these electrical attributes.

According to some embodiments, one or more of these sensors may be configured to measure/detect and transmit periodically, in real time or in near real time sensor data pertaining to these attributes.

Other sensors may be used to determine illumination attributes of the illumination system such as flux, intensity, intensity/power spatial distribution, temperature (heating) of the light fixture, color etc.

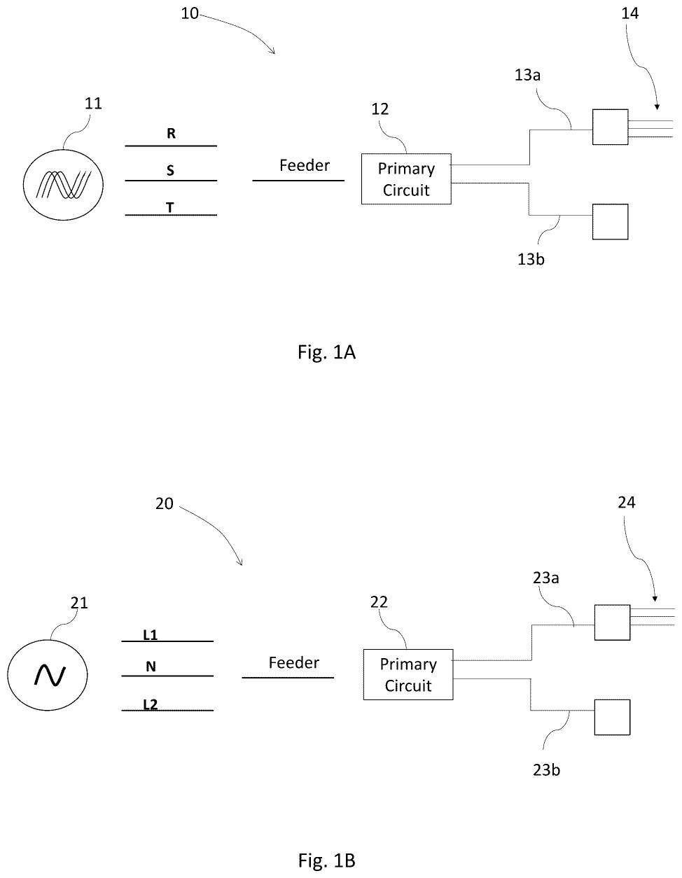

Electricity is typically delivered through a power grid of the illumination system, via a feeder that is often made up of two or three phases of electricity. These phases become independent primary circuits that are then often further divided into branch circuits (as illustrated in FIG. 1A).

An illumination system may be organized as a set of individual fixtures and/or as one or more ‘strings’ (collections) of multiple fixtures wired in ordinally on the same single contiguous circuit. A typical illumination system will include a multitude of independent light fixtures and/or strings of light fixtures connected as a “local grid”.

It is to be noted that the terms “light fixture(s)” and “fixture(s)” may be used interchangeably herein and may refer to any illumination device that includes one or more light sources (and optionally other components such as a holding apparatus such as poste, a fixture housing etc.).

It is to be noted that the terms “electrical circuit” and “circuit” may be used interchangeably herein having the same meaning of an electrical circuit.

It is to be noted that the terms “electrical local grid” and “local grid” may be used interchangeably herein having the same meaning of an electrical wiring network connecting the light fixtures of the illumination system and powered by connecting to at least one main power supply source.

According to some embodiments a power supply source may include for example, a municipal/global/central/regional electricity main grid ultimately powered by at least one power station connecting to the local grid of the illumination system via one or more electrical connections.

Different independent light fixtures and/or strings of light fixtures may belong to the same circuit of the local grid or they may belong to different circuits of the local grid of the illumination system. Different circuits may have the same phase or different phases.

It is important to balance the load demands as equally as possible across all phases.

It is important not to overload a circuit through inrush current demand or through steady-state current demand.

Aspects of disclosed embodiments pertain to systems and methods for determination of one or more attributes of an electrical local grid of an illumination system that includes multiple light fixtures electrically connected through the local grid to a main pour supply source.

According to some embodiments, the analysis system uses at least one processing module configured at least to: receive data pertaining to one or more electrical attributes of the local grid from one or more sensors; and process the received data to determine, based on the processing of the received data, one or more attributes of the local grid of the illumination system.

According to some embodiments, the one or more attributes of the local grid of the illumination system, may pertain to one or more of:
failures of one or more of the light fixtures or one or more components of one or more of the light fixtures of the illumination system;
failures in the local grid;
updated and/or general power demand of at least one light fixture of the illumination system;
inrush current of one or more of the light fixtures of the illumination system;
one or more phases of the electrical power of one or more of the light fixtures of the illumination system;
one or more voltage drops of one or more of the light fixtures of the illumination system;
sub-unity power factor in power of one or more of the light fixtures of the illumination system;
overload in one or more electrical circuits of the local grid of the illumination system;
relative positioning of the light fixtures of the illumination system over the local grid, in relation to the local grid and/or to one or more other light fixtures of the illumination system;
geolocation of each light fixture of the illumination system;
layout of the local grid and/or of the light fixtures of the illumination system over the local grid.

According to some embodiments, the analysis system may further include or receive data from one or more sensors, each sensor may be configured, for example, to one or more of:
sense one or more electrical attributes of at least one of the light fixtures and/or of the grid of the illumination system;
sense illumination attributes of at least one of the light fixtures;
sense one or more phases of electrical signals delivered and/or outputted to/from at least one of the light fixtures; and/or
sense timing of one or more phases of the electrical signals delivered and/or outputted to/from at least one of the light fixtures;
sense one or more electrical attributes of the local grid;
sense a change in the local grid from previously established ‘normal’ benchmarks;
sense electrical attributes of a main grid and/or the power supply source connectable to the local grid of the illumination system for suppling power thereto.

According to some embodiments, each sensor being associated with one or more of the light fixtures of the illumination system.

According to some embodiments, the analysis system may include or be part of a monitoring and control system, configured also to control at least some of the light fixtures of the illumination system based on the determined or sensed characteristics of the light fixtures and/or of the local grid of the illumination system. The controlling of at least some of the light fixtures may be done, for instance, via controllers, where each controller may be associated with a different specific light fixture of the illumination system and may be located in proximity to, attached to or embedded in the light fixture it is associated with.

According to some embodiments, the sensors may include for example a timing device that is synchronized with other timing devices of the other fixture devices of the illumination system, for determining timing of each phase of an alternating current (AC) supplied to the light fixture associated with the specific timing device, for determining which light fixtures of the illumination system share the same phase.

Each controller may also be configured to receive control data or control signals from the control and monitoring system and control the respective light fixture accordingly, for example, by controlling illumination characteristics of the light fixture associated therewith such as fixture's operation mode such as switching mode and/or timing thereof, dimming level and/or timing thereof, one or more light sources of the specific light fixture for being operated/switched/dimming-controlled, etc.

According to some embodiments, the at least one processing module may be further configured to generate a grid map of the local grid of the illumination system, where the grid map or parts thereof may be configured for being displayable via one or more user devices. The generated grid map may enable visually displaying of the determined one or more attributes of the local grid of the illumination system.

According to some embodiments, the analysis system may further be configured for detecting changes in the one or more attributes of the local grid; and displaying in real time or near real time the detected changes in the one or more attributes of the local grid over the generated grid map.

According to some embodiments, the grid map may enable visual presentation of relative position/location of each light fixture of the illumination system and/or the wiring (grid) layout of the local grid in relation to the light fixtures'positions/locations.

According to some embodiments, the analysis system may additionally or alternatively be configured to determine in real time or near real time one or more updated required control operations for controlling one or more of the light fixtures of the illumination system, via one or more controllers attached to, embedded in or located in proximity to the light fixtures of the illumination system, for increasing illumination power consumption efficiency and/or for increasing illumination efficiency. Illumination and/or power consumption efficiency may also depend on additional illumination requirements, which may depend, for example, on distances between light fixtures, minimum and maximum output power and distribution thereof for each light fixture, time of the day, ambient light conditions, weather conditions in the area of the illumination system, and the like. For example, the one or more updated control operations can be determined based on obtained updated illumination requirements of the illumination system, which are determined by the at least one processing module based on the determined one or more attributes of the local grid and additional dynamic and/or static parameters values of the illumination system, such as temperature, weather condition, ambient light condition, time of the day, etc.

According to some embodiments, the increasing/improving of the power consumption efficiency of the illumination system may be done by one or more of:
automatically and dynamically setting a timing of a power up (on-switching) of one or more of the light fixtures of the illumination system, to minimize the impact of inrush current and/or voltage drop and/or sub-unity power factor along at least one string or at least one circuit of the local grid; and/or
automatically and dynamically adapting dimming properties of each light fixture of the illumination system to minimize the impact of current and/or voltage variations and/or sub-unity power factor along at least one string or circuit of the local grid.

According to some embodiments, the analysis system may further include or use one or more sensors for sensing one or more attributes of one or more of: the local grid, a main power supply source feeding the local grid, and/or one or more of the light fixtures of the illumination system. For example, the one or more sensors may include one or more of: a timing device, a clock, a voltage sensor, a current sensor, an optical sensor for sensing one or more optical attributes of one or more of the light fixtures, a positioning sensor.

According to some embodiments, each timing device (clock) of each light fixture of the illumination system may be synchronized with other timing devices of corresponding other light fixtures of the illumination system, e.g. for identifying light fixtures of the same phase, circuit and/or string in the local grid of the illumination system, by identifying the phase of the alternating current (AC) delivered to each specific light fixture. Light fixtures having the same AC phase may be therefore associated to the same string or circuit in the local grid. This may also enable determining or estimating relative downstream position/location of each light fixture in the same string or circuit. In this way, at least some of the electrical attributes of the local grid may be determined.

Embodiments of disclosed systems and methods may also be able to create and introduce probing signals or semaphores into electrical circuits of the local grid for example, for simulating an inrush current, a voltage drop and/or for increasing or decreasing a power factor. Through an automated process of exploration, using probing signals and/or semaphores and analysis of the sensors'readings, the structure of the local grid or one or more parts thereof may be determined/assessed.

According to some embodiments, each light fixture with an installed controller and sensor(s) can be identified as stand-alone, or string connected. The circuit that each light fixture with an installed controller and sensor(s) is associated with, can be discerned, enabling thereby identification of an ordinal position of each light fixture on a string of the local grid, in relation to one or more other light fixtures of that same string in the local grid.

According to some embodiments, the analysis system may also include a communication module for enabling communication between the at least one processing module thereof and one or more of:
each of the one or more sensors;
at least one external information source for obtaining, for example, other information associated with the illumination system, its local grid and/or its location such as, yet not limited to: updated weather condition of the area of the illumination system, known technical attributes of each light fixture such as maximum and/or minimum power capacity, power factor, color(s), dimming span, estimated inrush current required for on-switching the light fixture, etc. ; and/or
at least one control center, configured to control a main power supply source supplying power to the illumination system via the local grid, for example, for obtaining information relating to the main power supply and/or for detection of power supply failures/impairments etc.

Combining the exploration data with optionally: phase data and/or geolocation data (that may be obtained from sensors), a comprehensive map of the local grid supplying power from the main power supply source to the light fixtures of the illumination system, can be automatically generated.

Additional details may optionally be provided such as information pertaining to the main power supply source for identifying other attributes of the local grid of the illumination system, such as electricity feeders' locations, phase, primary circuits, and branch circuit of the local grid, to enhance the mapping of the local grid (i.e. the determination of the one or more attributes of the local grid), generating a “grid map” that can be easily displayed through user devices' display means.

The automatically generated grid map optionally enhanced with phase, geolocation, source and other obtained or deduced data may be used to statically optimize/minimize/reduce operations of the illumination system by adjusting configuration of the (already existing) illumination system, by controlling illumination of the illumination system for increasing efficiency in power consumption of the light fixtures of the illumination system, and/or by generating a grid plan for yet to be installed illumination system. The systems and methods of disclosed embodiments may also be configured to generate an operation plan for the illumination system for further increasing power consumption efficiency, improve illumination efficiency etc.

According to some embodiments, the term “improving illumination efficiency” may refer to, for example, extending of a life-span of light fixtures of the illumination system, reducing operational and/or abrupt power/energy consumption of the light fixtures and/or other devices of the illumination system, optimizing/improving phase load, and/or preventing structural failures (such as circuit overload for example) of the local grid.

According to some embodiments, the improving of the illumination efficiency may be achievable by one or more of:
automatically setting the timing of the power up of one or more light fixtures to minimize the impact of inrush current and/or voltage drop and/or sub-unity power factor along a string or circuit;
automatically setting the timing of the power down of one or more light fixtures to minimize the impact of current variations and/or voltage variations and/or sub-unity power factor along a string or circuit; and/or
automatically adapting dim levels of the light fixtures to minimize/reduce the impact of current variations and/or voltage variations and/or sub-unity power factor along at least one string or circuit of the local grid.

The generated grid map optionally enhanced with phase, geolocation, and source and identity data may be combined with live sensor data from the one or more sensors for example, to dynamically improve operations of the illumination system e.g., by adjusting operations in response to detected attributes obtained from the one or more sensors.

The automatically generated grid map may enable identification location of faults/impairments in the local grid such as line breakage, poor connection, etc.

The analysis systems and methods may also enable to automatically notify circuit adjacent devices outside of the illumination system of conditions, faults, and issues that those external devices may use to adjust their operations for example, for:
protecting and/or improving the operation of, these external devices.
changing the operating condition(s) of the external devices in order to affect the supply electricity conditions of the power supply sourcing, for changing the operational conditions of the illumination system or one or more components thereof.

According to some embodiments, the analysis system may further be configured to generate plans for an illumination systems and local grids thereof for a specific area of interest (AOI) to be illuminated by an illumination system, based on one or more obtained requirements and limitations. This means generating an “illumination system plan” including a layout of specific determined/selected light fixtures to be used, their spatial layout (position/location) and specific local grid connectivity between those light fixtures and optionally also connectivity to other devices used for operating the local grid and/or the light fixtures of the illumination system.

The illumination system planning may be enabled by using a designated planning platform operable via one or more user devices.

According to some embodiments, the planning platform may be configured for providing, for example, visual and other tools for one or more of:
obtaining or generating a visual display of the AOI;
placement and selection of light fixtures in the AOI visual display;
designing the electrical connections (local grid) of the selected light fixtures;
determining and outputting/displaying of estimated impairments of the current design of the illumination system;
determining and proposing replacement light fixtures and/or local grid design adjustments for improving/optimizing illumination efficiency and/or power consumption efficiency of the illumination system being planned.

Additionally or alternatively, the planning platform may automatically generate an optimized illumination system plan upon obtaining the required AOI and optionally additional information pertaining, for example, to the AOI, user requirements/limitations, etc.

According to some embodiments, the planning platform may also enable providing estimated costs and/or purchasing tools/interface(s) for required illumination system equipment such as light fixtures, local grid equipment, etc.

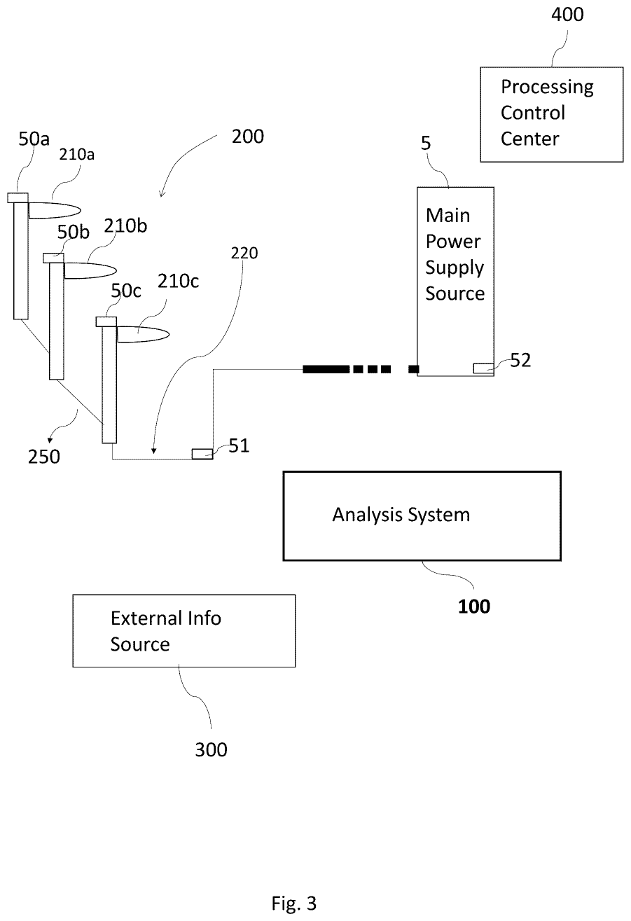

Reference is now made to FIG. 3, schematically illustrating an analysis system 100 that is associated with at least one illumination system such as illumination system 200, the analysis system being configured at least for determining one or more attributes of a local grid 220 of the illumination system 200, according to some embodiments.

The illumination system 200 may include multiple light fixtures such as light fixtures 210a-210c, all connected to a main power supply source 5 through the local grid 220.

Each light fixture 210a, 210b and 210c of the illumination system 200 may have a controller installed therein or attached thereto such controller 50, 50b or 50c, respectively. Each controller 50a/50b/50c may be associated with a different light fixture 210a, 210b and 210c of the illumination system 200 and may include one or more means for controlling one or more illumination attributes of the light fixture it is associated with, such as switching mode, dimming level, etc.

The analysis system 100 may use or include one or more sensors such as sensors 51 and 52, which may be located within the local grid, at the main power supply source 5 and/or sensors attached to, embedded in and/or located in proximity to the light fixtures 210a-210c. For example, each light fixture 210a/210b/210c may have at least one sensor/sensor embedded within its associated controller 50a/50b/50c.

According to some embodiments, one or more of the sensors may be configured to sense one or more electrical attributes of the local grid 220, the main power supply source 5, and/or of electrical and/or illumination attributes of at least one light fixture 210a/210b/210c of the illumination system 200.

The term “illumination attributes” used herein may refer to any one or more optical and/or electrical properties of a light fixture, the area being illuminated by the illumination system or one or more parts of that area.

According to some embodiments, as illustrated in FIG. 3, one or more external information sources such as external information source 300, may be used by the analysis system 100 for obtainment of additional information pertaining to the illumination system (such as type of each light fixture and other light fixtures' known technical properties, initial spatial layout of the light fixtures, etc.); to the main grid of the main power supply source 5, to the AOI in which the illumination system 200 is located, etc.

According to some embodiments, as illustrated in FIG. 3, the main power supply source may be controlled via a control center 400. The analysis system 100 may be configured such as to enable communicating with the control center 400 for receiving alerts, for example, pertaining to problems in the main power supply source (main grid), to send alerts to the control center 100 upon identification of problems in the power supply, etc.

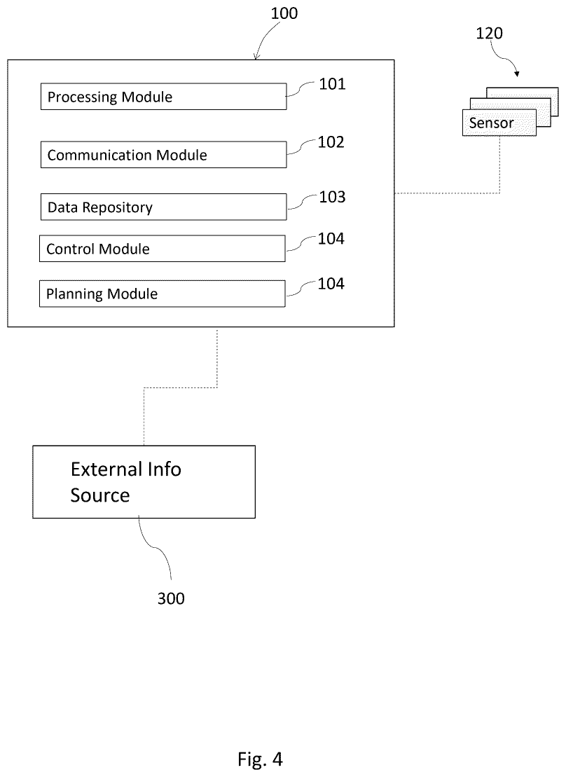

FIG. 4 schematically illustrates main components of the analysis system 100, according to some embodiments. The analysis system 100 may include one or more of:
(i) at least one processing unit such as processing module 101, configured, for example to receive and process data from one or more sensors 120, configured to sense one or more electrical, optical and/or environmental properties of the illumination system 200 and/or of the local grid supplying power that emanates from the main power supply source 5 to the light fixtures 210a-210c of the illumination system 200;
(ii) a communication module 102, configured for enabling the analysis system 100 to communicate with one or more of: the one or more sensors 120 and/or one or more external devices and/or units such as one or more external information sources such external information source 300, one or more user devices such as mobile phones, tablet devices, personal computer (PC) devices, etc.;
(iii) a data repository 103 for storing data of various types; and
(iv) a control module 104 at least for controlling one or more of the sensors being used.

According to some embodiments, the analysis system 100 may also include a planning module 105 configured for automatic or manual generation of illumination system plans, and optionally also for displaying and/of adjustment of generated illumination system plans.

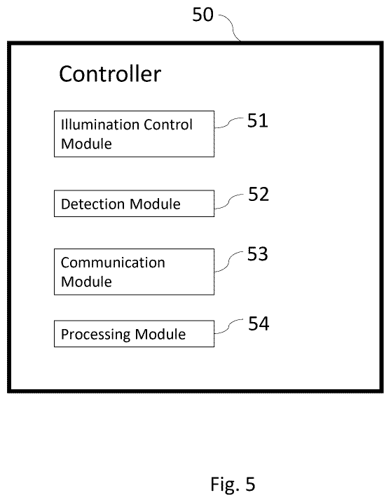

FIG. 5 schematically illustrates a controller 50 for controlling operation of a specific light fixture, according to some embodiments. The controller may include one or more of the following main components:
an illumination control module 51 configured for controlling one or more illumination properties of the specific light fixture such as illumination intensity and/or flux (dimming), switching mode, color(s) of output light, illumination distribution properties such as illumination Lux, illumination flux, etc.;
a detection module 52 which may include one or more sensors embedded in the detection module 52;
a communication module 53 for communicating with the analysis system 100 and/or with one or more external devices; and
a processing module, configured to receive and process data, e.g. for receiving data pertaining to one or more of: illumination switching signals/data; illumination control signals/data; sensor control signals/data, and the like.

According to some embodiments, the controller 50 may be designed for being embedded in or attached to the specific light fixture or a device connecting to the specific light fixture.

According to some embodiments the analysis system 100 may be part of a main processing and control unit or station, such as processing and control center 400, which may be located externally to the illumination system 200. Additionally or alternatively, the illumination system 200 and the analysis system 100 along with all sensors being used, may be part of a combined system.

According to some embodiments, the one or more sensors of the detection module 52 of the controller 50, may include one or more of: optical sensor(s) such as a camera, an illumination (lux) meter, a volt meter, a current meter, etc.

According to some embodiments, the sensor data arriving from all sensors of the analysis system and/or of the illumination system may be analysed/processed to determine one or more updated attributes of the (specific) local grid of the specific illumination system and/or its light fixtures, such as, yet not limited to one or more of the following attributes:
failures of one or more of the light fixtures or one or more components of one or more of the light fixtures of the illumination system and/or of the local grid;
failures in the local grid;
inrush current of one or more of the light fixtures of the illumination system;
one or more phases of the electrical power of one or more of the light fixtures of the illumination system;
voltage drops of one or more of the light fixtures of the illumination system;
sub-unity power factor in power of one or more of the light fixtures of the illumination system;
overload in one or more electrical circuits of the local grid of the illumination system;
relative positioning of the light fixtures of the illumination system over the local grid, in relation to the local grid and/or to one or more other light fixtures of the illumination system;
geolocation of each light fixture of the illumination system;
layout of the local grid and/or of the light fixtures of the illumination system.

According to some embodiments, the data processing may be configured/programmed such as to determin information/data that pertains to one or more electrical attributes of the local grid of the illumination system and/or of the illumination system such as information pertaining to relative positioning /ocation of each light fixture of the specific light fixture in relation to all other fixtures of the illumination system and/or electrical properties of each light fixture such as on-switching electrical power requirements/failures, ongoing or real time power consumption information of each light fixture, etc.

The analysis system may also serve as a monitoring system for ongoing or periodic monitoring at least electrical attributes of the local grid and/or of the illumination system associated therewith for sensing and determining of dynamic (updated) properties of the illumination and/or its local grid.

Additional non-sensory data may be obtained and used to determine local grid and/or illumination system attributes such as location data, updated weather data of the area of the illumination system, light fixtures' known typical/expected properties such as expected time of expiration, maximum and/or minimum power consumption properties, etc.

The analysis of updated sensor data and optionally also of non-sensory data may enable generating a grid map indicative of relative location of each light fixture of the illumination system over its local grid (i.e. illumination system layout) thereby enabling identification of the power supply arrangement of each light fixture over each string, each branch circuit and/or each primary circuit of the local grid of the illumination system.

This may enable easy and user-friendly identification of failures or inherent problems in the illumination layout of the wiring/circuitry of the illumination system, and may also enable improving illumination control, e.g., by planning the timing of on-switching of the light fixtures according to the relative location of each light fixture over its corresponding string and/or branch circuit at the local grid.

According to some embodiments the one or more sensors used for obtaining data for determining electrical attributes of the local grid and/or of the illumination system may include (e.g., highly accurate) timers or clocks, which are synchronized. Each clock may be associated with a different light fixture of the illumination system for timing the phase of the alternate current supplied to the specific light fixture for determining positioning of the respective light fixture over the power supply line (e.g., over the specific string and/or branch circuit) of the local grid.

According to some embodiments, each clock may be embedded in or attached to a controller of the light fixture it is associated with.

The updated time reading from each clock of each light fixture may be transmitted to the analysis system (e.g., from the controller of the specific light fixture), where the updated reading from each clock may be used as the data being processed by the analysis system for determining the one or more electrical attributes of the illumination system and/or the local grid thereof.

Comparing readings across clocks allows the analysis system to identify which other light fixtures share the same phase. This allows fixtures to be clustered by phase.

According to some embodiments, probing signals or semaphores can be introduced into the electrical circuit (voltage drop, power factor, and/or inrush current) for determining electrical attributes of the illumination system and/or local grid thereof.

For example, one or more sensors on each controller of each light fixture can detect these probing signals or semaphores to determine voltage drop, power factor, and/or inrush current of the specific light fixture. The controller may als0 probing signal(s) may also be configured to generate and introduce these probing signals into the circuitry of the specific light fixture it is associated with.

Through an automated process of exploration using probing signals and analysis of sensor readings, the electrical networking layout (local grid) of the illumination system can be discovered and/or assessed.

Each light fixture with an installed controller and sensor can be identified as stand-alone, or string connected. The circuit that each light fixture is assigned to can be discerned.

The ordinal position of each light fixture on a string from the first fixture that is source adjacent to any subsequent downstream location can be identified.

Combining the obtained exploration data with optionally: phase data and/or geolocation data, a comprehensive map of the local grid of the illumination system's light fixtures can be automatically generated.

Non-sensory data/information may optionally be supplied regarding the main power supply source and identity of electricity feeders, phase, primary circuits, and branch circuits, to improved local grid mapping accuracy and/or future illumination control, e.g., by statically optimizing operational characteristics of the illumination system e.g., for extending fixture life, reduce energy consumption, optimize phase load, and/or prevent local grid structural failures (e.g., circuit overloads) etc.

According to some embodiments, the optimization may include one or more of:
automatic setting of on-switching timing of one or more light fixtures along a string or circuit of the local grid, such as to minimize the impact of phenomena such as inrush current, voltage drop and/or sub-unity power factor;
automatic setting of the timing of the power supply down along a string or circuit of the local grid of one or more light fixtures to minimize the impact of current variations and/or voltage variations and/or power factor variations;
automatic adjustment of dim levels of one or more light fixtures along a string or a circuit of the local grid, to minimize the impact of current variations and/or voltage variations and/or sub-unity power factor along a string or circuit.

The automatically generated grid map of the illumination system, may be displayed and may also be enhanced with indication of additional information such as with phase, geolocation, and/or source and identity data. The grid map display may also be combined with live (e.g., real time or near real time) sensor data to dynamically optimize controlling/adjustment of the illumination system by determining updated required control operations in response to sensor readings to extend fixture life, reduce energy consumption, optimize phase load, optimize illumination, and/or prevent structural failures (such as circuit overload) of the local grid.

According to some embodiments, the analysis system may be further configured to identify circuitry and/or other impairments in the illumination system and/or local grid thereof and optionally also indicate identified impairments and optionally also send and/or display alerts indicative of identified impairments.

According to some embodiments the generated grid map and/or the raw data of sensor readings and non-sensory data may all be obtained and processed by a central processing and control center, which may be associated with several illumination systems, for providing a concentrated analysis and monitoring services for various illumination systems located in various locations.

According to some embodiments, the generated grid map may be displayable via a designated software application operable by user devices.

According to some embodiments, the analysis system may also be configured to determine one or more updated required control operations for controlling the light fixtures of the illumination system, such as, yet not limited to: protecting, changing and/or optimizing the operation of one or more of the light fixtures (such as dimming control, on-switching timing control, etc.), optimizing, adjusting, changing and/or improving operation of one or more external devices, e.g., in order to affect the power supply conditions of the illumination system.

According to some embodiments, there is provided a planning tool or platform that may enable users to preplan an illumination system local grid by obtaining premeditated estimated or manufacturer's published electrical and optical attributes of light fixtures and of the area/structure/facility to be illuminated by the illumination system by generating predicted grid maps of the local grid and adjusting it to comply with customer/user requirements, the limitations of the area to be illuminated, and for improving illumination and power consumption efficiency/use.

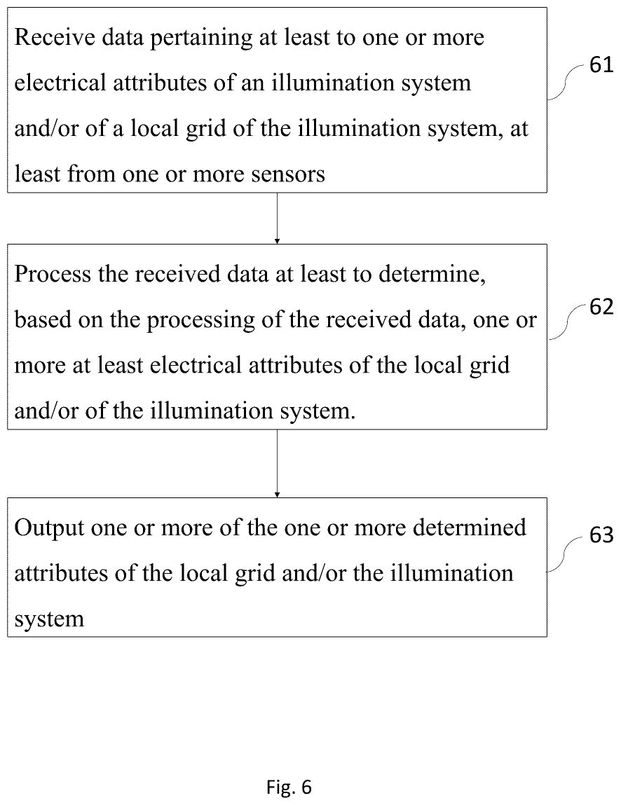

Reference is now made to FIG. 6, showing a flowchart which schematically illustrate main steps of a method at least for determining one or more electrical attributes of an illumination system that includes multiple light fixtures connected via a local (electricity) grid. The method may include the main steps of:
receiving data pertaining at least to one or more electrical attributes of an illumination system and/or of a local grid of the illumination system, at least from one or more sensors (step 61) such as AC time data;
processing the received data at least to determine, based on the processing of the received data, one or more electrical attributes of the local grid and/or of the illumination system (step 62); and
outputting one or more of the one or more determined attributes of the local grid and/or the illumination system including at least one electrical attribute of the illumination system, e.g., by generating a grid map indicative at least of the positioning of each light fixture of the illumination system over the local grid thereof.

In the drawings and descriptions above, identical reference numerals may indicate components that are common to different embodiments or configurations.

Unless specifically stated otherwise, as apparent from the above discussions, it is appreciated that throughout the specification discussions utilizing terms such as “obtaining”, “identifying”, “performing”, “providing” “moving”, “determining”, “instructing” and the like, may include one or more actions and/or processes of at least one computer or a processor device that manipulate and/or transform data into other data, said data represented as physical quantities, e.g., such as electronic quantities, and/or said data representing the physical objects. The terms “computer”, “processor”, “processing resource”, “processing circuitry”, and “controller” should be expansively construed to cover any kind of electronic device with data processing capabilities, including, by way of non-limiting example, a personal desktop/laptop computer, a server, a computing system, a communication device, a smartphone, a tablet computer, a smart television, a processor (e.g. digital signal processor (DSP), a microcontroller, a field programmable gate array (FPGA), an application specific integrated circuit (ASIC), etc.), a group of multiple physical machines sharing performance of various tasks, virtual servers co-residing on a single physical machine, any other electronic computing device, and/or any combination thereof.

The operations in accordance with the teachings above may be performed by a computer specially constructed for the desired purposes or by a general-purpose computer specially configured for the desired purpose by a computer program stored in a non-transitory computer readable storage medium. The term “non-transitory” is used herein to exclude transitory, propagating signals, but to otherwise include any volatile or non-volatile computer memory technology suitable to the application.

As used in this document, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) is included in at least one embodiment of the presently disclosed subject matter. Thus, the appearance of the phrase “one case”, “some cases”, “other cases” or variants thereof does not necessarily refer to the same embodiment(s).

It is appreciated that, unless specifically stated otherwise, certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

It will also be understood that the system according to the presently disclosed subject matter can be implemented, at least partly, as a suitably programmed computer. Likewise, the presently disclosed subject matter contemplates a computer program being readable by a computer for executing the disclosed method. The presently disclosed subject matter further contemplates a machine-readable memory tangibly embodying a program of instructions executable by the machine for executing the disclosed method.

1. An analysis system for determination of one or more attributes of a local grid of an illumination system, wherein the illumination system comprises multiple light fixtures electrically connected through the local grid, the analysis system comprising at least:
at least one processing module configured to:
receive data pertaining at least to one or more electrical attributes of the local grid and/or of the light fixtures of the illumination system, from one or more sensors; and
process the received data to determine, based on the processing of the received data, one or more attributes of the local grid and/or of the illumination system.

2. The analysis system of claim 1, wherein the one or more attributes pertain to one or more of:
state of one or more of the light fixtures or one or more components of one or more of the light fixtures of the illumination system;
failures in the local grid and/or in one or more of the light fixtures of the illumination system;
inrush current of one or more of the light fixtures of the illumination system;
one or more phases of the electrical power of one or more of the light fixtures of the illumination system;
one or more voltage drops of one or more of the light fixtures of the illumination system;
sub-unity power factor in power of one or more of the light fixtures of the illumination system;
overload in one or more electrical circuits of the local grid of the illumination system;
relative position of the light fixtures of the illumination system over the local grid, in relation to the local grid and/or to one or more other light fixtures of the illumination system;
geolocation of each light fixture of the illumination system;
layout of the local grid and/or of the light fixtures of the illumination system.

3. The analysis system of claim 1, wherein each sensor is configured to one or more of:
sense one or more electrical attributes of at least one of the light fixtures;
sense illumination attributes of at least one of the light fixtures;
sense one or more phases of electrical signals delivered and/or outputted to/from at least one of the light fixtures; and/or
sense timing of one or more phases of the electrical signals delivered and/or outputted to/from at least one of the light fixtures;
sense one or more electrical attributes of the local grid;
sense a change in the local grid from previously established ‘normal’ benchmarks;
sense electrical attributes of a power supply source connectable to the local grid of the illumination system for suppling power thereto.

4. A method for determination of one or more attributes of an electrical local grid of an illumination system, wherein the illumination system comprises multiple light fixtures electrically connected through the local grid, the method including a processing circuitry configured for:
receiving data pertaining at least to one or more electrical attributes of the local grid and/or of the illumination system, at least from one or more sensors; and
processing the received data to determine, based on the processing of the received data, one or more attributes of the illumination system and/or its local grid.

5. The method of claim 4, wherein the one or more attributes pertain to one or more of:
state of one or more of the light fixtures or one or more components of one or more of the light fixtures of the illumination system;
failures in the local grid and/or in one or more of the light fixtures of the illumination system;
inrush current of one or more of the light fixtures of the illumination system;
one or more phases of the electrical power of one or more of the light fixtures of the illumination system;
one or more voltage drops of one or more of the light fixtures of the illumination system;
sub-unity power factor in power of one or more of the light fixtures of the illumination system;
overload in one or more electrical circuits of the local grid of the illumination system;
relative position of the light fixtures of the illumination system over the local grid, in relation to the local grid and/or to one or more other light fixtures of the illumination system;
geolocation of each light fixture of the illumination system;
layout of the local grid and/or of the light fixtures of the illumination system.

6. The method of any one or more of claim 4 further comprising one or more of:
obtaining one or more electrical attributes of at least one of the light fixtures;
obtaining illumination attributes of at least one of the light fixtures;
obtaining one or more phases of electrical signals delivered and/or outputted to/from at least one of the light fixtures; and/or
obtaining timing of one or more phases of the electrical signals delivered and/or outputted to/from at least one of the light fixtures;
obtaining one or more electrical attributes of the local grid;
obtaining a change in the local grid from previously established ‘normal’ benchmarks;
obtaining electrical attributes of a power supply source connectable to the local grid of the illumination system for supplying power thereto.

7. The method of claim 6, wherein the obtaining of the one or more electrical, timing, phases, electrical and/or illumination attributes of at least one of the light fixtures of the illumination system is done by using one or more sensors, each sensor being associated with one or more of the light fixtures of the illumination system.

8. The method system of claim 4 further comprising controlling at least some of the light fixtures of the illumination system based on the determined one or more attributes of the local grid of the illumination system and/or updated attributes of the specific light fixture, wherein the controlling of at least some of the light fixtures is done via controllers, wherein each controller is located in proximity to, attached to or embedded in a light fixture from the light fixtures of the illumination system.

9. The method of claim 4, wherein each sensor comprises a timing device that is synchronized with other timing devices of the other fixture devices of the illumination system, for determining timing of each phase of an alternating current (AC) supplied to the light fixture associated with the specific timing device, for determining which light fixtures of the illumination system share the same phase.

10. The method of claim 4 further comprising determining updated required control operations for controlling and/or adjusting one or more operation properties of one or more of the light fixtures of the illumination system for increasing illumination and/or power consumption efficiency.

11. The method of claim 10 further comprising sending determined updated required control operations information to each controller of each light fixture of the illumination system determined to require one or more control operations, wherein each controller is configured to receive updated required operation control actions data or signals and control the light fixture it is associated therewith accordingly.

12. The method of claim 10, wherein the one or more updated required control operations are determined also based on obtained updated illumination requirements and/or limitations of the illumination system.

13. The method of claim 10, wherein the increasing illumination and/or power consumption efficiency is done by one or more of:
automatically and dynamically setting a timing of a power up of one or more of the light fixtures of the illumination system, to minimize the impact of inrush current and/or voltage drop and/or sub-unity power factor along at least one string or a circuit of the local grid;
automatically and dynamically adapting dimming properties of each light fixture of the illumination system to minimize the impact of current and/or voltage variations and/or sub-unity power factor along at least one string or circuit of the local grid.

14. The method of claim 4 further comprising generating and displaying a grid map of the local grid of the illumination system, wherein the grid map or parts thereof is configured for being displayable via one or more user devices.

15. The method of claim 14, wherein the generated grid map enables displaying of the determined one or more attributes of the local grid of the illumination system and/or one or more attributes of the illumination system including at least relative positions of each the light fixtures of the illumination over the local grid.

16. The method of claim 15 further comprising:
detecting changes in the one or more attributes of the local grid; and
displaying in real time or near real time the detected changes in the one or more attributes of the local grid over the generated grid map.

17. The method of claim 4, wherein the one or more sensors comprise one or more of: a timing device, a clock, a voltage sensor, a current sensor, an optical sensor for sensing one or more optical attributes of one or more of the light fixtures, a positioning sensor.

18. The method of claim 4 further comprising enabling communication with one or more of:
each of the one or more sensors, configured to detect one or more attributes pertaining to the local grid and/or to the illumination system;
at least one external information source; and/or
at least one control center, configured to control a main power supply source supplying power to the illumination system via the local grid.

19. The method of claim 4 further comprising providing a planning platform, configured to enable generation of illumination system plans local grids thereof for a specific area of interest (AOI) based on one or more of:
obtained illumination requirements and/or limitations;
obtained power consumption requirements and/or limitations;
user input information;
AOI information.

20. The method of claim 19, wherein the planning platform is further configured for one or more of:
automatic generation of an optimized illumination plan based at least of information pertaining to the AOI in which the illumination system is to be located;
enabling users to manually generate and/or adjust illumination system plans via one or more planning tools of the planning platform;
displaying of generated illumination system plans.
